(19) United States
(12) Patent Application Publication
(10) Pub. No.: US 2026/0068048 A1
(43) Pub. Date: Mar. 5, 2026

(54) PRINTED CIRCUIT BOARD

(71) Applicant: SAMSUNG ELECTRO-MECHANICS CO., LTD., Suwon-si (KR)

(72) Inventors: Sang Ho JEONG, Suwon-si (KR); Chang Hwa PARK, Suwon-si (KR); Sang Yun LEE, Suwon-si (KR); Hyun Hu LEE, Suwon-si (KR)

(73) Assignee: SAMSUNG ELECTRO-MECHANICS CO., LTD., Suwon-si (KR)

(21) Appl. No.: 19/187,302

(22) Filed: Apr. 23, 2025

(30) Foreign Application Priority Data
Aug. 30, 2024 (KR) 10-2024-0117346

(51) Int. Cl. H05K 1/11; H01L 23/00; H05K 1/03; H05K 1/18; H05K 3/42

(52) U.S. Cl. CPC H05K 1/116; H05K 1/0306; H05K 1/181; H05K 3/42; H05K 2201/09563; H05K 2201/09581; H05K 2201/10212

(57) ABSTRACT

A printed circuit board is provided. The printed circuit board includes a glass layer having a through-hole; an insulating material disposed within the through-hole and having a via hole; and a metal via disposed within the via hole. The metal via includes a first metal layer that is substantially conformally disposed on a wall surface of the via hole, a second metal layer that is substantially conformally disposed on the first metal layer, and a third metal layer disposed on the second metal layer and filling at least a portion of the via hole.

### CROSS-REFERENCE TO RELATED APPLICATIONS

This application claims benefit of priority to Korean Patent Application No. 10-2024-0117346 filed on Aug. 30, 2024, with the Korean Intellectual Property Office, the disclosure of which is incorporated herein by reference in its entirety.

### TECHNICAL FIELD

The present disclosure relates to a printed circuit board.

Recently, enlarged areas, greater layering and miniaturization are required for high performance of package substrates. Meanwhile, a Copper Clad Laminate (CCL) is usually used as a core substrate included in a package substrate, but in the case of CCL, warpage is likely to occur due to low modulus and high coefficient of thermal expansion, and there are also limitations in implementing microcircuits. Accordingly, there is demand for a core substrate including a new material, such as glass, which has a high modulus and a low coefficient of thermal expansion to suppress warpage and also has a smooth surface to facilitate the implementation of microcircuits. However, in the case of glass cores, there may be difficulties in securing adhesion during the process of forming a seed metal layer in a via hole. Additionally, during a fill plating process, non-plating may occur in a central portion of the via hole, which may result in via open defects.

### SUMMARY

An aspect of the present disclosure is to provide a printed circuit board that may secure the adhesion of a seed metal layer and may prevent the occurrence of non-plating during fill plating in the case of forming a via hole in a glass layer, such as a glass core, and filling the via hole with plating.

One of the various solutions proposed by the present disclosure is to form a through-hole in a glass layer, such as a glass core, fill the through-hole with an insulating material, form a via hole in the insulating material, and form a metal via including a plurality of seed layers in the via hole.

For example, a printed circuit board according to an example embodiment may include: a glass layer having a through-hole; a first insulating material disposed within the through-hole, and having a first via hole; and a first metal via disposed within the first via hole, and the first metal via may include a first metal layer in which at least a portion thereof is substantially conformally disposed on a wall surface of the first via hole, a second metal layer in which at least a portion thereof is substantially conformally disposed on the first metal layer, and a third metal layer disposed on the second metal layer and filling at least a portion of the first via hole.

For example, a printed circuit board according to an example embodiment may include: a core portion including a glass core having a through-hole, an insulating material disposed within the through-hole and having a via hole, and a metal via disposed within the via hole; and a build-up portion including an insulating body disposed on the core portion, one or more interconnection layers respectively disposed on or within the insulating body, and one or more via layers respectively disposed within the insulating body, and the metal via may include a first metal layer in which at least a portion thereof is conformally disposed on a wall surface of the via hole, a second metal layer in which at least a portion thereof is conformally disposed on the first metal layer, and a third metal layer disposed on the second metal layer and filling at least a portion of the via hole.

One of the various effects of the present disclosure is to provide a printed circuit board that may secure the adhesion of a seed metal layer and may prevent the occurrence of non-plating during fill plating in the case of forming a via hole in a glass layer, such as a glass core, and filling the via hole with plating.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board;

FIGS. 3A to 3M are cross-sectional views schematically illustrating various shapes of a through-hole, a via-hole, and a metal via that may be applied to the printed circuit board of FIG. 2;

FIG. 4 is a process diagram schematically illustrating an example of manufacturing the printed circuit board of FIG. 2;

FIG. 5 is a cross-sectional view schematically illustrating a modified example of the printed circuit board of FIG. 2;

FIG. 6 is a cross-sectional view schematically illustrating another example of a printed circuit board;

FIG. 7 is a process diagram schematically illustrating an example of manufacturing the printed circuit board of FIG. 6;

FIG. 8 is a cross-sectional view schematically illustrating a modified example of the printed circuit board of FIG. 6;

FIG. 9 is a cross-sectional view schematically illustrating another example of a printed circuit board;

FIG. 10 is a process diagram schematically illustrating an example of manufacturing the printed circuit board of FIG. 9;

FIG. 11 is a cross-sectional view schematically illustrating a modified example of the printed circuit board of FIG. 9;

FIG. 12 is a cross-sectional view schematically illustrating another example of a printed circuit board;

FIG. 13 is a process diagram schematically illustrating an example of manufacturing the printed circuit board of FIG. 12; and

FIG. 14 is a cross-sectional view schematically illustrating a modified example of the printed circuit board of FIG. 12.

### DETAILED DESCRIPTION

Hereinafter, the present disclosure will be described with reference to the accompanying drawings. In the drawings, the shapes and sizes of the elements may be exaggerated or reduced for clearer description.

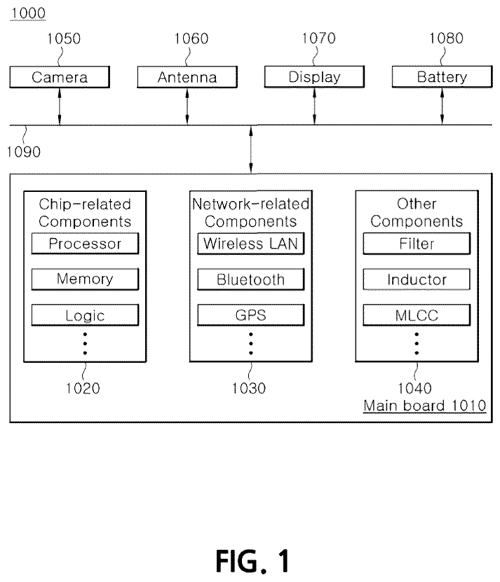

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto and may be any other electronic device that processes data.

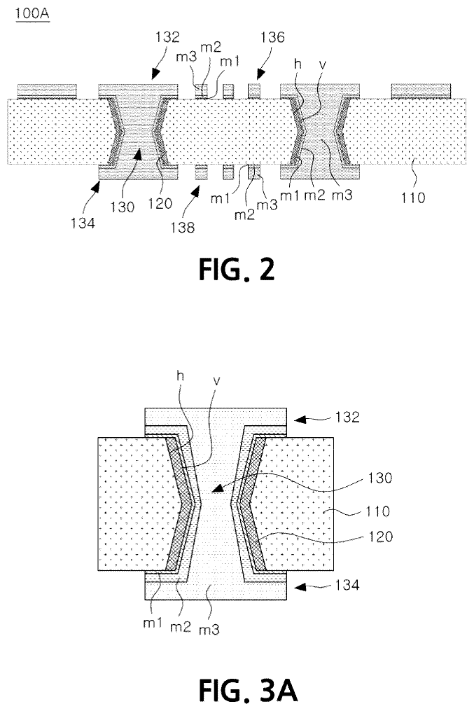

FIG. 2 is a cross-sectional view schematically illustrating an example of a printed circuit board.

Referring to FIG. 2, a printed circuit board 100A may include a glass layer 110 having a through-hole h, an insulating material 120 disposed within the through-hole h and having a via hole v, and a metal via 130 disposed within the via hole v. The metal via 130 may include a first metal layer m1 in which at least a portion thereof is substantially conformally disposed on a wall surface of the via hole v, a second metal layer m2 in which at least a portion thereof is substantially conformally disposed on the first metal layer m1, and a third metal layer m3 disposed on the second metal layer m2 and filling at least a portion of the via hole v. The first and second metal layers m1 and m2 may be seed metal layers, and the third metal layer m3 may be a fill-plated metal layer.

In this manner, in the printed circuit board 100A, a through-hole h penetrating between an upper surface and a lower surface of the glass layer 110 in the glass layer 110 may be formed, and after filling the through-hole h with the insulating material 120, the via hole v penetrating between an upper surface and a lower surface of the insulating material 120 may be formed within the through-hole h, and the metal via 130 including the plurality of seed metal layers m1 and m2 and the fill-plated metal layer m3 may be formed in the via hole v. That is, the plurality of seed metal layers m1 and m2 may be formed in the via hole v formed in the insulating material 120 rather than the glass layer 110, so that sufficient coverage may be secured, and the adhesion problem of the seed metal layers m1 and m2 may be effectively improved. Additionally, since the fill-plated metal layer m3 may be formed after securing sufficient coverage, a via open problem due to the occurrence of underplating may be effectively improved.

Meanwhile, the insulating material 120 may include an organic insulating material. For example, the insulating material 120 may include a thermosetting resin such as an epoxy resin, a thermoplastic resin such as a polyimide, or an inorganic filler and/or an organic filler together with the resin. For example, the insulating material 120 may be an Ajinomoto Build-up Film (ABF), or the like, in which case, it may be easier to form the insulating material 120 in the through-hole h, and it may also be easier to process a via hole v in the insulating material 120, but the present disclosure is not limited thereto.

Additionally, the seed metal layers m1 and m2 may be formed by sputtering and electroless plating. For example, the first metal layer m1 may be formed by sputtering and may include, for example, a stuffer metal. Additionally, the second metal layer m2 may be formed by electroless plating and may include, for example, chemical copper. In this case, adhesion may be secured through the first metal layer m1, and coverage may be secured through the second metal layer m2. For example, when the thickness of the glass layer 110 is increased, a region in which the first metal layer m1 is not formed may be present on a wall surface in a center region of the via hole v, but even in this case, the second metal layer m2 may cover a region of the wall surface of the via hole v in which the first metal layer m1 is not formed, and thus, coverage may be secured. The second metal layer m2 formed by electroless plating may be thicker than the first metal layer m1 formed by sputtering. The thickness may be confirmed in a cut-section or a cut-plane of the metal via 130, and when the thickness is not constant, an average value at five arbitrary points may be compared.

Additionally, the first metal layer m1 may include a plurality of sputtering layers, and may include, for example, a first sputtering layer connected to the wall surface of the via hole v and a second metal layer m2, for example, a second sputtering layer connected to chemical copper. The first sputtering layer may include titanium (Ti) in terms of bonding strength with the insulating material 120, and the second sputtering layer may include copper (Cu) in terms of bonding strength with the second metal layer m2, but the present disclosure is not limited thereto. When the second sputtering layer includes copper (Cu) and the second metal layer m2 includes chemical copper, a nano void may be formed at a boundary between the sputtered copper and the chemical copper, which may be confirmed by a high-resolution Scanning Electron Microscope (SEM), Transmission Electron Microscope (TEM), Scanning Transmission Electron Microscopy (STEM), Focused Ion Beam (FIB), or the like. Additionally, the shape and size of the grains may be confirmed and compared using SEM, TEM, STEM, FIB, or the like, to distinguish the grains. Additionally, when analysis is performed using Energy Dispersive X-ray Spectroscopy (EDX), or the like, the concentration of nickel (Ni) may be relatively concentrated in chemical copper, which may also be used to distinguish the grains.

Additionally, the third metal layer m3, for example, the fill-plated metal layer m3, may be formed by electrolytic plating. For example, the third metal layer m3 may include electrolytic copper. Since the seed metal layer m1 and m2 described above may be formed on the wall surface of the via hole v, at least a portion of the via hole v may be easily filled with the third metal layer m3 without any special plating defects. For example, via open defects such as non-plating occurring in a central portion of the via hole v may be prevented. Meanwhile, chemical copper and electrolytic copper may be distinguished by confirming and comparing the shape and size of grains using the SEM, the TEM, the STEM, the FIB, or the like. Additionally, when analysis is performed using EDX, in chemical copper and electrolytic copper, the concentration of nickel (Ni) may be relatively concentrated in chemical copper, which may also be used to distinguish the grains.

The printed circuit board 100A may further include a first metal pattern 132 connected to an upper side of the metal via 130 and a second metal pattern 134 connected to a lower side of the metal via 130. The first and second metal patterns 132 and 134 may be lands and/or pads of the metal via 130. If necessary, different metal patterns 136 and 138 may be further disposed on an upper surface and a lower surface of the glass layer 110, and the different metal patterns 136 and 138 may include a line pattern and a pad pattern. The first and second metal patterns 132 and 134, and the different metal patterns 136 and 138, may include the first to third metal layers m1, m2, and m3 described above, respectively. For example, the first metal pattern 132 may include a first metal layer m1 substantially conformally extending onto an upper surface of the insulating material 120 and an upper surface of the glass layer 110, a second metal layer m2 substantially conformally extending onto the first metal layer m1 from the upper surface of the insulating material 120 and the upper surface of the glass layer 110, and a third metal layer m3 extending onto the second metal layer m2 from the upper surface of the first insulating material 120 and the upper surface of the glass layer 110 and protruding to an upper side of the via hole v. Additionally, the second metal pattern 134 may include a first metal layer m1 substantially conformally extending onto a lower surface of the insulating material 120 and a lower surface of the glass layer 110, a second metal layer m2 substantially conformally extending onto the first metal layer m1 from the lower surface of the insulating material 120 and the lower surface of the glass layer 110, and a third metal layer m3 extending onto the second metal layer m2 from the lower surface of the insulating material 120 and the lower surface of the glass layer and protruding to a lower side of the via hole v.

Meanwhile, the extending portion of the first metal layer m1 may be in direct contact with the upper surface and lower surface of the insulating material 120 and the upper surface and lower surface of the glass layer 110, respectively. For example, the upper surface and lower surface of the glass layer 110 may not be covered with the insulating material 120. For example, a stack structure in which the glass layer 110/insulating material 120/first metal layer m1/second metal layer m2/third metal layer m3 are disposed in order may be formed inside the via hole v, while a stack structure in which the glass layer 110/first metal layer m1/second metal layer m2/third metal layer m3 are disposed in order may be formed on the upper surface and/or lower surface of the glass layer 110. Accordingly, unnecessary thickness increase may be prevented. Additionally, since a pattern may be directly formed on the surface of the glass layer 110, this may be easier to fine pitch. Meanwhile, the upper surface of the glass layer 110 may be substantially coplanar with the upper surface of the insulating material 120, and the lower surface of the glass layer 110 may be substantially coplanar with the lower surface of the insulating material 120. Accordingly, it may be possible to more easily provide a substantially flat surface on the upper and/or lower surface of the glass layer 110.

Hereinafter, components of the printed circuit board 100A will be illustrated in more detail with reference to the drawings.

The glass layer 110 may include glass, which is an amorphous solid. The glass may include, for example, pure silicon dioxide (about 100% SiO₂), soda-lime glass, borosilicate glass, and alumino-silicate glass. However, the present disclosure is not limited thereto, and alternative glass materials, for example, fluorine glass, phosphate glass, chalcogen glass, or the like, may also be used as materials. Additionally, other additives may be included to form a glass having specific physical properties. These additives may include calcium carbonate (e.g., lime) and sodium carbonate (e.g., soda), as well as magnesium, calcium, manganese, aluminum, lead, boron, iron, chromium, potassium, sulfur, and antimony, and carbonates and/or oxides of these elements and other elements. The glass layer 110 may be distinguished from organic insulating materials including, for example, glass fiber (Glass Fiber, Glass Cloth or Glass Fabric), specifically, Copper Clad Laminate (CCL), and Prepreg (PPG). For example, the glass layer 110 may include a glass plate.

The through-hole h may penetrate between the upper surface and the lower surface of the glass layer 110. For example, the through-hole h may be a Through Glass Via (TGV). The through-hole h may have an hourglass shape having the narrowest width in a central portion there thereof on the cross-section penetrating through the through-hole h, but the present disclosure is not limited thereto. The glass layer 110 may have a plurality of such through-holes h. The plurality of through-holes h may be spaced apart from each other and may be formed in the glass layer 110. The number of the plurality of through-holes h may not be particularly limited.

The insulating material 120 may include an organic insulating material. For example, the insulating material 120 may include a thermosetting resin such as an epoxy resin, a thermoplastic resin such as a polyimide, or an inorganic filler and/or an organic filler together with the resin. For example, the insulating material 120 may be Ajinomoto Build-up Film (ABF), and the like, in which case it may be easier to form the insulating material 120 in the through-hole h, and it may also be easier to process a via hole v in the insulating material 120, but the present disclosure is not limited thereto. The insulating material 120 may be disposed between the glass layer 110 and the metal via 130 within the through-hole h, and may continuously surround a side surface of the metal via 130.

The via hole v may penetrate between the upper surface and the lower surface of the insulating material 120 within the through-hole h. For example, the via hole v may be a Through Via (TV). The via hole v may have an hourglass shape having the narrow est width in a central portion thereof on the cross-section penetrating through the via hole v, but the present disclosure is not limited thereto. When a plurality of through-holes h are formed in the glass layer 110, the insulating material 120 may be respectively disposed in the plurality of through-holes h, and a plurality of via holes v may be respectively formed in the insulating material 120.

The metal via 130 may include a metal. The metal may include, for example, copper (Cu), aluminum (Al), silver (Ag), tin (Sn), gold (Au), nickel (Ni), lead (Pb), titanium (Ti), and/or alloys thereof. For example, the metal via 130 may include first to third metal layers m1, m2 and m3. The first and second metal layers m1 and m2 may be seed metal layers formed using sputtering and electroless plating, and the third metal layer m3 may be a metal layer that is fill-plated using electroplating. The first metal layer m1 may include a plurality of sputtering layers. For example, the first metal layer m1 may include a composite layer of a sputtered titanium layer and a sputtered copper layer, and the second metal layer m2 may include chemical copper, and the third metal layer m3 may include electrolytic copper. The metal via 130 may perform various functions depending on the design. For example, the metal via 130 may include a signal via, a power via, and a ground via. When the plurality of via holes v are formed, a plurality of metal vias 130 may be disposed within each of the plurality of via holes v.

Each of the first and second metal patterns 132 and 134 may include a metal. The metal may include, for example, copper (Cu), aluminum (Al), silver (Ag), tin (Sn), gold (Au), nickel (Ni), lead (Pb), titanium (Ti), and/or alloys thereof. For example, each of the first and second metal patterns 132 and 134 may include the first to third metal layers m1, m2 and m3 described above. Each of the first and second metal patterns 132 and 134 may perform various functions according to the design. For example, the first and second metal patterns 132 and 134 may include a signal pattern, a power pattern, and a ground pattern, and each of these patterns may have a pad and/or land shape. When the plurality of metal vias 130 are formed, a plurality of first metal patterns 132 and a plurality of second metal patterns 134 may be respectively disposed on an upper side and a lower side of the plurality of metal vias 130.

Each of the other metal patterns 136 and 138 may include a metal. The metal may include, for example, copper (Cu), aluminum (Al), silver (Ag), tin (Sn), gold (Au), nickel (Ni), lead (Pb), titanium (Ti), and/or alloys thereof. For example, each of the other metal patterns 136 and 138 may include the first to third metal layers m1, m2 and m3 described above. The other metal patterns 136 and 138 may each perform various functions according to the design, and may include, for example, a signal pattern, a power pattern, and a ground pattern. These patterns may have various shapes such as a line, a plane, a pad, and a land.

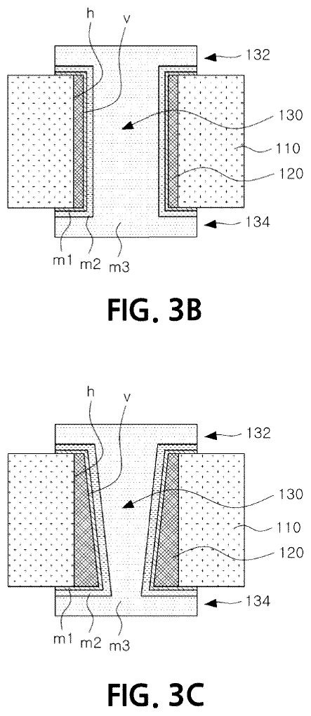

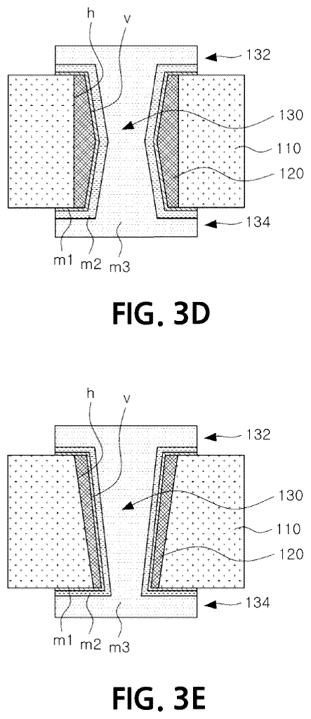

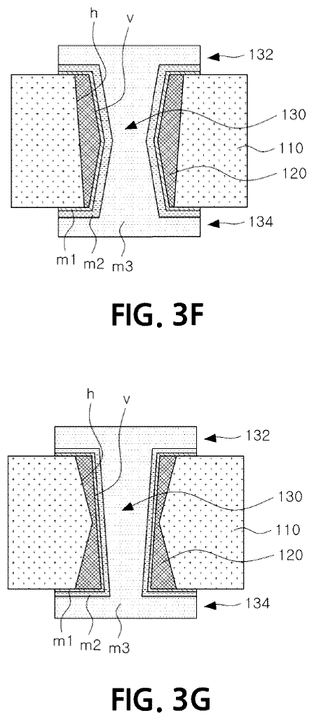

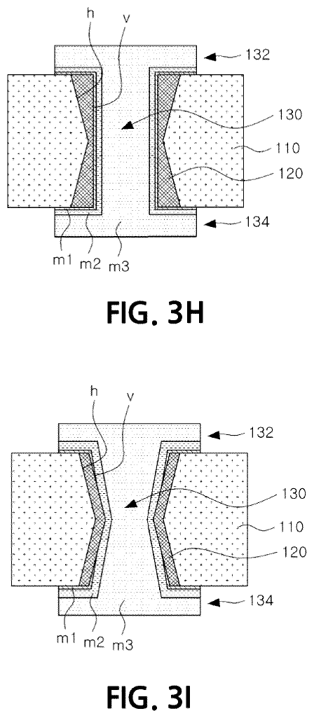

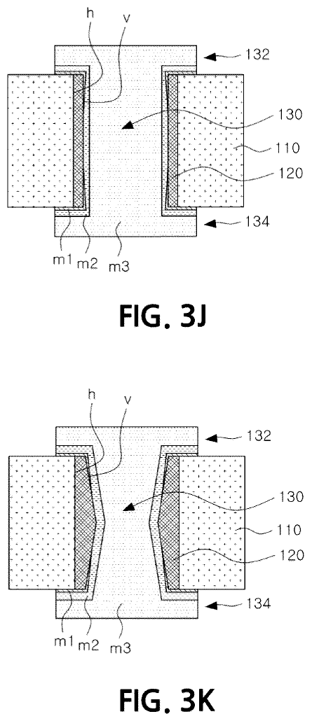

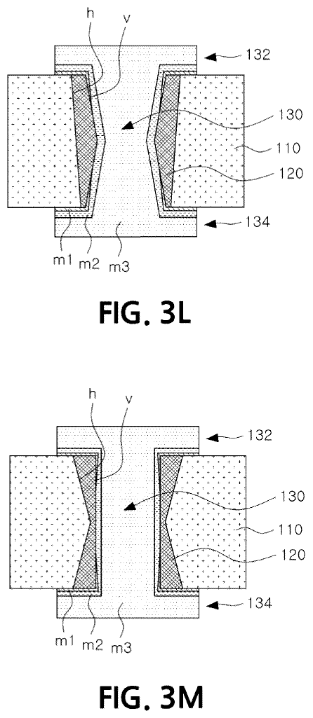

FIGS. 3A to 3M are cross-sectional views schematically illustrating various shapes of through-holes, via holes, and metal vias that may be applied to the printed circuit board of FIG. 2.

Referring to the drawings, in the cross-sections penetrating through the through-holes h and via holes v, the shapes of the through-holes h and the via holes v may substantially correspond to each other, or may be independent of each other. For example, referring to FIG. 3A, each of the through-holes h and the via holes v may have an hourglass shape with the narrowest width in a central portion thereof. Alternatively, referring to FIG. 3B, each of the through-holes h and the via holes v may have a rectangular shape with substantially vertical wall surfaces. Alternatively, referring to FIG. 3C, the through-hole h may have a substantially vertical rectangular shape, while the via hole v may have a tapered shape in which a width of an upper end thereof is wider than a width of a lower end thereof. Alternatively, referring to FIG. 3D, the through-hole h may have a substantially vertical rectangular shape, while the via hole v may have an hourglass shape with a narrowest width in a central portion thereof. Alternatively, referring to FIG. 3E, each of the through-hole h and the via hole v may have a tapered shape in which a width of an upper end thereof is wider than a width of a lower end thereof. Alternatively, referring to FIG. 3F, the through-hole h may have a tapered shape in which a width of an upper end thereof is wider than a width of a lower end thereof, while the via hole v may have an hourglass shape with a narrowest width in a central portion thereof. Alternatively, referring to FIG. 3G, the through-hole h may have an hourglass shape with the narrowest width in a central portion thereof, while the via hole v may have a tapered shape in which a width of an upper end thereof is wider than a width of a lower end thereof. Alternatively, referring to FIG. 3H, the through-hole h may have an hourglass shape with the narrowest width in a central portion thereof, while the via hole v may have a rectangular shape with substantially vertical wall surfaces. Meanwhile, referring to FIGS. 31 to 3M, in the structure illustrated in each of FIGS. 3A, 3B, 3D, 3F, and 3H described above, since a step coverage of the sputter is not sufficient, there may be a region in which the first metal layer m1 is not formed on a wall surface in the central region of the via hole v, but, even in this case, the second metal layer m2 may cover a region in which the first metal layer m1 is not formed on the wall surface of the via hole v, and therefore, sufficient coverage may be secured. For example, a stack structure in which the glass layer 110/insulating material 120/second metal layer m2/third metal layer m3 are disposed in order may be formed in the central portion of the via hole v. For example, the second metal layer m2 may be in direct contact with the insulating material 120 in the central portion of the via hole v. Additionally, other descriptions may be applied substantially identically to the contents described for the printed circuit board 100A.

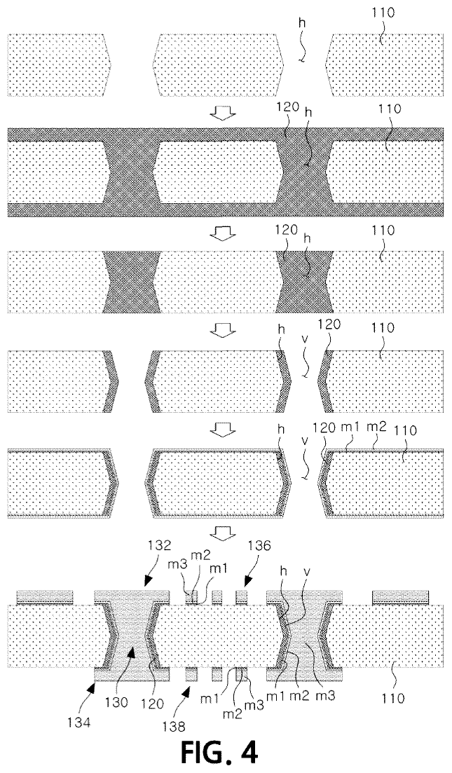

FIG. 4 is a process diagram schematically illustrating an example of manufacturing a printed circuit board of FIG. 2.

Referring to FIG., first, a through-hole h may be formed in a glass layer 110. The glass layer 110 may be a glass plate, or the like. The through-hole h may be formed by a chemical method, such as etching, blasting, laser, or plasma, and/or a mechanical method. Next, an insulating material 120 may be applied to the glass layer 110 to fill the through-hole h. For example, ABF lamination, or the like, may be used. Depending on the need, the insulating material 120 may be formed of a plurality of layers, and boundaries between the plurality of layers may be distinguished or not distinguished. Next, a portion of the insulating material 120 disposed on an upper surface and a lower surface of the glass layer 110 may be removed. The removal of the insulating material 120 may be performed using a polishing process such as Chemical Mechanical Planarization (CMP), or etching. Next, a via hole v may be formed in the insulating material 120. Laser processing using carbon dioxide gas may be used for processing the via hole v. If necessary, a desmear treatment may be performed after processing the via hole v. Next, sputtering and electroless plating may be performed sequentially to form first and second metal layers m1 and m2 on the glass layer 110 and inside the via hole v. Next, a third metal layer m3 may be formed on the glass layer 110 and inside the via hole v using a circuit process including electrolytic plating. Through this, a metal via 130 and first and second metal patterns 132 and 134 and other metal patterns 136 and 138 may be formed. A printed circuit board 100A may be manufactured through a series of processes. Other descriptions may be substantially identically applied to the contents described as being present in the printed circuit board 100A.

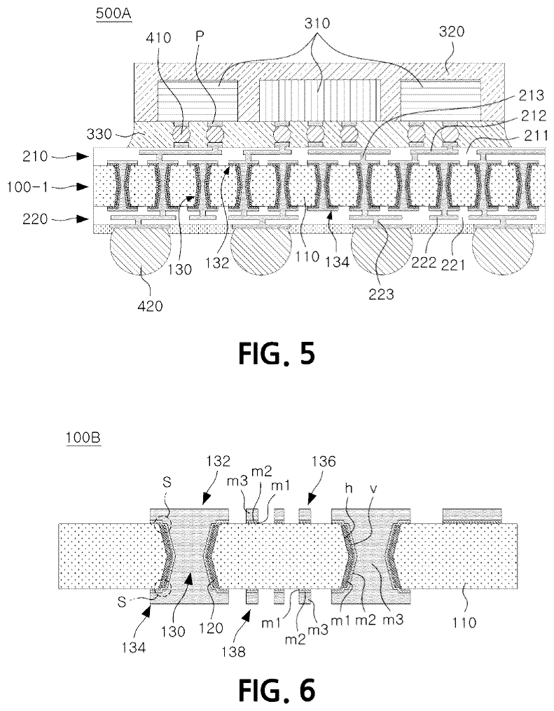

FIG. 5 is a cross-sectional view schematically illustrating a modified example of the printed circuit board of FIG. 2.

Referring to FIG. 5, a printed circuit board 500A may be a multilayer printed circuit board including a core portion 100-1, a first build-up portion 210 disposed on an upper side of the core portion 100-1, and a second build-up portion 220 disposed on a lower side of the core portion 100-1. For example, the printed circuit board 500A may be used as a Flip-Chip Board (FCB), a Ball Grid Array (BGA), an interposer substrate, a package substrate, or the like. However, the present disclosure is not limited thereto, and may be applied to various other types of substrates. In this case, the core portion 100-1 may include the structure described as being present in the printed circuit board 100A described above, and therefore, may include substantially the same technical features as described above.

The printed circuit board 500A may further include a plurality of semiconductor chips 310 mounted on the first build-up portion 210. The plurality of semiconductor chips 310 may be surface-mounted on the first build-up portion 210 through a plurality of first electrical connection metals 410, respectively. For example, a plurality of terminals P of each of the plurality of semiconductor chips 310 may be connected to an uppermost pad pattern of one or more first interconnection layers 212 of the first build-up portion 210 through the plurality of first electrical connection metals 410. If necessary, the printed circuit board 500A may further include a molding material 320 covering the plurality of semiconductor chips 310, an underfill material 330 disposed between the plurality of semiconductor chips 310 and the first build-up portion 210 and surrounding the plurality of first electrical connection metals 410, and/or a plurality of second electrical connection metals 420 disposed on a lower side of the second build-up portion 220.

Hereinafter, components of the printed circuit board 500A will be illustrated in more detail with reference to the drawings.

The core portion 100-1 may include a glass core 110, a plurality of metal vias 130 respectively penetrating through the glass core 110, a plurality of first metal patterns 132 respectively disposed on an upper surface of the glass core 110 and respectively connected to an upper side of the plurality of metal vias 130, and a plurality of second metal patterns 134 respectively disposed on a lower surface of the glass core 110 and respectively connected to the lower side of the plurality of metal vias 130. For example, the core portion 100-1 may include the structure described for the printed circuit board 100A above. Additionally, various shapes illustrated in FIGS. 3A to 3M may also be applied to the core portion 100-1. Duplicate descriptions thereof will be omitted.

The first build-up portion 210 may include a first insulating body 211 disposed on an upper side of the core portion 100-1, one or more first interconnection layers 212 arranged on or within the first insulating body 211, and one or more first via layers 213 disposed on or within the first insulating body 211. The second build-up portion 220 may include a second insulating body 221 disposed on a lower side of the core portion 100-1, one or more second interconnection layers 222 disposed on or within the second insulating body 221, and one or more second via layers 223 disposed on or within the second insulating body 221.

Each of the first and second insulating bodies 211 and 221 may include an organic insulating material. The organic insulating material may include a thermosetting resin such as an epoxy resin, a thermoplastic resin such as a polyimide, or an inorganic filler, an organic filler, and/or glass fiber (glass cloth, glass fabric) along with the resin. For example, each of the first and second insulating bodies 211 and 221 may include Prepreg (PPG), an Ajinomoto Build-up Film (ABF), Photo Imageable Dielectric (PID), and Solder Resist (SR), but the present disclosure is not limited thereto. If necessary, each of the first and second insulating bodies 211 and 221 may be formed of a plurality of layers. In this case, adjacent layers may have boundaries with each other, but may also be integrated with each other without boundaries. Each layer may include substantially the same organic insulating material, but is not limited thereto, and may include different organic insulating materials.

Each of the first and second interconnection layers 212 and 222 may include a metal. The metal may include copper (Cu), aluminum (Al), silver (Ag), tin (Sn), gold (Au), nickel (Ni), lead (Pb), titanium (Ti), and/or alloys thereof. The first and second interconnection layers 212 and 222 may include preferably copper (Cu), but the present disclosure not limited thereto. Each of the first and second interconnection layers 212 and 222 may perform various functions according to the design. For example, the first and second interconnection layers 212 and 222 may include a signal pattern, a power pattern, and a ground pattern. Each of the patterns may have various shapes such as a line, a plane, a pad, and a land. Each of the first and second interconnection layers 212 and 222 may include a seed layer and a plating layer. The seed layer may be formed by electroless plating or sputtering, or may be formed using both the electroless plating and the sputtering. The plating layer may be formed by electrolytic plating. Each of the first and second interconnection layers 212 and 222 may be formed of a plurality of layers, and may have the same number of layers in this case, but the present disclosure is not limited thereto.

Each of the first and second via layers 213 and 223 may include a metal. The metal may include copper (Cu), aluminum (Al), silver (Ag), tin (Sn), gold (Au), nickel (Ni), lead (Pb), titanium (Ti), and/or alloys thereof. The first and second via layers 213 and 223 may include, preferably, copper (Cu), but the present disclosure is not limited thereto. Each of the first and second via layers 213 and 223 may perform various functions depending on the design. For example, the first and second via layers 213 and 223 may include a signal via, a power via, and a ground via. Each of the first and second via layers 213 and 223 may include a filled VIA in which a via hole is filled with a metal, but may also include a conformal VIA in which a metal is disposed along a wall surface of the via hole. Each of the first and second via layers 213 and 223 may provide an electrical path within the first and second build-up portions 210 and 220, and may also provide an electrical path between the core section 100-1 and the first and second build-up portions 210 and 220, respectively. Each of the first and second via layers 213 and 223 may have a tapered shape in cross-section, and for example, may have shapes tapered in opposite directions in cross-section. Each of the first and second via layers 213 and 223 may include the same seed layer and plating layer as the first and second interconnection layers 212 and 222. Each of the first and second via layers 213 and 223 may be formed of a plurality of layers.

The semiconductor chip 310 may include an integrated circuit (IC) die in which several hundred to several million of elements are integrated into a single chip. In this case, the integrated circuit may be, for example, a logic chip such as a central processor (e.g., CPU), a graphics processor (e.g., GPU), a field programmable gate array (FPGA), a digital signal processor, an encryption processor, a microprocessor, a microcontroller, an application processor (e.g., AP), an analog-to-digital converter, and an application-specific IC (ASIC), but the present disclosure is not limited thereto, and the integrated circuit may be a memory chip such as a volatile memory (e.g., DRAM), a non-volatile memory (e.g., ROM), a flash memory, a High Bandwidth Memory (HBM), or another type such as a Power Management IC (PMIC).

The semiconductor chip 310 may be formed based on an active wafer, and in this case, silicon (Si), germanium (Ge), gallium arsenide (GaAs), or the like, may be used as a base material forming each body. Various circuits may be formed on the body. A connection pad may be formed on the body, and the connection pad may include a conductive material such as aluminum (Al), copper (Cu). The semiconductor chip 310 may be a bare die, and in this case, a terminal P such as a metal bump may be disposed on the connection pad. A semiconductor chip 200 may be a packaged die, and in this case, a redistribution layer may be additionally formed on the connection pad, and a terminal P such as a metal bump may be disposed on the redistribution layer.

The molding material 320 may protect the semiconductor chip 310 and may provide mechanical strength in the semiconductor packaging process. From this perspective, the molding material 320 may include an Epoxy Molding Compound (EMC) having excellent protection performance, thermal properties, mechanical strength, electrical insulation, and environmental stability. However, the present disclosure is not limited thereto, and other polymer materials may be used in addition to epoxy.

The underfill material 330 may fill a gap between the semiconductor chip 310 and the first build-up portion 210 in the semiconductor packaging process to improve mechanical strength, and resistance to thermal and mechanical stress may be increased. The underfill material 330 may include a resin material that may perform this function, such as Capillary Underfill (CUF), No-Flow Underfill (NUF), and Molded Underfill (MUF), but the present disclosure is not limited thereto.

The first and second electrical connection metals 410 and 420 may connect a printed circuit board 100B to other substrates or electronic components. Each of the first and second electrical connection metals 410 and 420 may be formed of a conductive material, such as solder, or the like, but this is only an example and the material is not particularly limited thereto. The first and second electrical connection metals 410 and 420 may be balls, pins, or the like, respectively. The first and second electrical connection metals 410 and 420 may be formed as multilayer structures or single layers, respectively. When formed as multilayer structures, the first and second electrical connection metals 410 and 420 may include a copper pillar and a solder formed on the copper pillar, and when formed as a single layer, the first and second electrical connection metals 410 and 420 may include tin-silver solder or copper, but the present disclosure is not limited thereto. The first and second electrical connection metals 410 and 420 may be provided in plural, respectively.

Any other description may be substantially identically applied to the contents described as being present in the printed circuit board 100A.

FIG. 6 is a cross-sectional view schematically illustrating another example of a printed circuit board.

Referring to FIG. 6, the printed circuit board 100B may be configured so that an upper surface of the insulating material 120 may be recessed downwardly from an upper surface of the glass layer 110, and a lower surface of the insulating material 120 may be recessed upwardly from the lower surface of the glass layer 110, in the printed circuit board 100A described above. Accordingly, the first and second metal patterns 132 and 134 may have a step structure S on the upper surface and the lower surface of the insulating material 120, respectively. For example, each of the first to third metal layers m1, m2 and m3 may have a step portion on the upper surface and the lower surface of the insulating material 120.

In this manner, the printed circuit board 100B basically has a structure similar to that of the printed circuit board 100A described above, and may thus substantially include the technical effects described above. Additionally, since the printed circuit board 100B has a step structure S, this may be more effective in dispersing thermal and mechanical stress and may improve the characteristics of high-frequency signals by diversifying the electrical signal path, and may help reduce electromagnetic interference (EMI). Additionally, the heat generation problem may be alleviated by allowing heat to spread over a wide area rather than being concentrated in one place, and the electrical contact resistance may be reduced by increasing the electrical contact area, and the reliability may be improved by increasing the physical contact area.

Meanwhile, the various shapes of the through-hole h and the via hole v illustrated in FIGS. 3A to 3M may also be applied to the printed circuit board 100B. For example, the step structure S described above may be applied to the upper surface and the lower surface of the insulating material 120 in the various shapes described above. Additionally, the contents described as being present in the printed circuit board 100A may be substantially applied in the same manner.

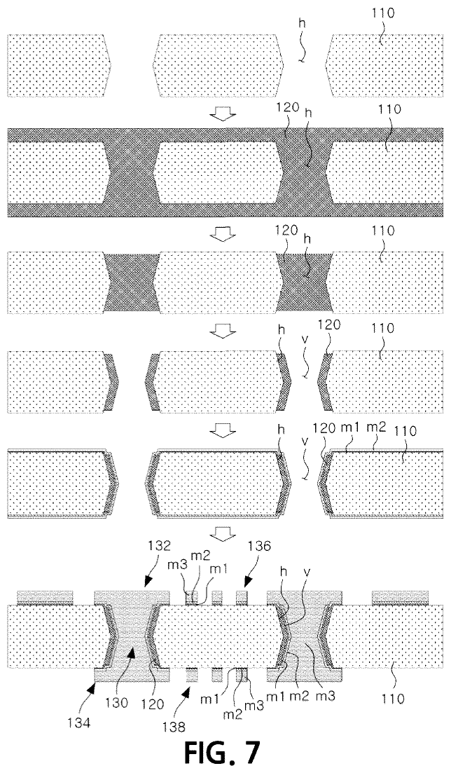

FIG. 7 is a process diagram schematically illustrating an example of manufacturing a printed circuit board of FIG. 6.

Referring to FIG. 7, first, a through-hole h may be formed in a glass layer 110. Next, an insulating material 120 may be applied to the glass layer 110 to fill the through-hole h. Next, a portion of the insulating material 120 disposed on the upper surface and the lower surface of the glass layer 110 may be removed. In this case, due to excessive etching of the insulating material 120, the upper surface and the lower surface of the insulating material 120 may have a step portion from the upper surface and the lower surface of the glass layer 110, respectively. Next, a via hole v may be formed in the insulating material 120. Next, first and second metal layers m1 and m2 may be formed on the glass layer 110 and inside the via hole v. Next, a third metal layer m3 may be formed on the glass layer 110 and inside the via hole v. Through this, a metal via 130 and first and second metal patterns 132 and 134 and other metal patterns 136 and 138 may be formed. Through a series of processes, the printed circuit board 100B described above may be manufactured. Other descriptions may be substantially identically applied to the printed circuit boards 100A and 100B and a manufacturing example of the printed circuit board 100A.

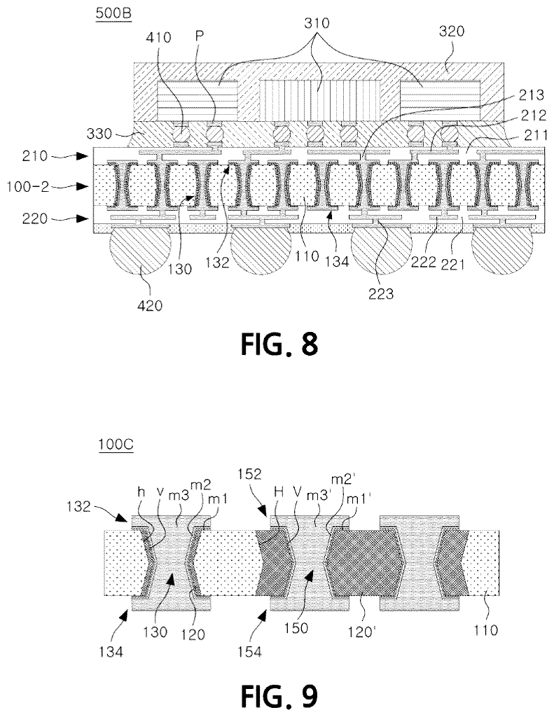

FIG. 8 is a cross-sectional view schematically illustrating a modified example of the printed circuit board of FIG. 6.

Referring to FIG. 8, a printed circuit board 500B may be configured so that the structure described as being present in the printed circuit board 100B described above instead of the structure described as being present in the printed circuit board 100A described above may be included in a core portion 100-2, in the printed circuit board 500A described above. Accordingly, the technical features and technical effects described as being present in the printed circuit boards 100A, 100B and 500A described above may be substantially identically included therein. Additionally, various shapes illustrated in FIGS. 3A to 3M may be applied to the core portion 100-2. Duplicate descriptions thereof will be omitted. Additionally, other descriptions may be applied substantially identically to the contents described for printed circuit boards 100A, 100B, and 500A.

FIG. 9 is a cross-sectional view schematically illustrating another example of a printed circuit board.

Referring to FIG. 9, a printed circuit board 100C may be configured so that in the printed circuit board 100A described above, the glass layer 110 may further have a through-portion H spaced apart from the through-hole h, a second insulating material 120′ having a plurality of second via holes V may be disposed within the through-hole h, and a plurality of second metal vias 150 may be disposed within each of the plurality of second via holes V. Each of the plurality of second metal vias 150 may include a fourth metal layer m1′ in which at least a portion thereof is substantially conformally disposed on each wall surface of the plurality of second via holes V, a fifth metal layer m2′ in which at least a portion thereof is substantially conformally disposed on the fourth metal layer m1′, and a sixth metal layer m3′ disposed on the fifth metal layer m2′ and filling each of the plurality of second via holes V. The fourth and fifth metal layers m1′ and m2′ may be seed metal layers m1′ and m2′, and the sixth metal layer m3′ may be a fill-plated metal layer m3′.

In this manner, since the printed circuit board 100C basically has a structure similar to that of the printed circuit board 100A described above, the printed circuit board 100C may substantially include the technical effects described above. Additionally, the second insulating material 120′ may be disposed in the through-portion H greater in size than the through-hole h, the plurality of second via holes V may be formed in the second insulating material 120′, and a plurality of second metal vias 150 may be disposed in each of the plurality of second via holes V. This structure may be easily applied when a close area of vias is required within the substrate. Additionally, the structure may allow for easier control of via pitch.

Meanwhile, a plurality of second metal vias 150 may each be connected to a respective third metal pattern 152 on the upper side. Each of the plurality of third metal patterns 152 may include a fourth metal layer m1′ substantially conformally extending onto an upper surface of the second insulating material 120′, a fifth metal layer m2′ substantially conformally extending onto the fourth metal layer m1′ from the upper surface of the second insulating material 120′, and a sixth metal layer m3′ extending onto the fifth metal layer m2′ from the upper surface of the second insulating material 120′ and protruding to an upper side of each of the plurality of second via holes V. An upper surface of each of the plurality of third metal patterns 152 may be substantially coplanar with an upper surface of the first metal pattern 132.

Additionally, the plurality of second metal vias 150 may be respectively connected to a plurality of fourth metal patterns 154 on upper and lower sides. Each of the plurality of fourth metal patterns 154 may include a fourth metal layer m1′ substantially conformally extending onto a lower surface of the second insulating material 120′, a fifth metal layer m2′ substantially conformally extending onto the fourth metal layer m1′ from the lower surface of the second insulating material 120′, and a sixth metal layer m3′ extending onto the fifth metal layer m2′ from the lower surface of the second insulating material 120′ and protruding to a lower side of each of the plurality of second via holes V. A lower surface of each of the plurality of fourth metal patterns 154 may be substantially coplanar with a lower surface of the second metal pattern 134.

Additionally, the second insulating material 120′ may be substantially the same as the first insulating material 120, and for example, when the first insulating material 120 is formed, the second insulating material 120′ may also be formed based on the same material and process. Additionally, the fourth to sixth metal layers m1′, m2′ and m3′ may be substantially the same as the first to third metal layers m1, m2 and m3, and for example, when the first to third metal layers m1, m2 and m3 are formed, the fourth to sixth metal layers m1′, m2′ and m3′ may also be formed based on the same material and process.

Meanwhile, the various shapes of the through-hole h and the via hole v illustrated in FIGS. 3A to 3M may also be applied to the printed circuit board 100C. For example, the various shapes described above may be substantially identically or similarly applied to the through-hole h and the first via hole v, and the through-portion H and the plurality of second via holes V. With respect to other descriptions, the contents described by the printed circuit boards 100A and 100B may be applied thereto in substantially the same manner.

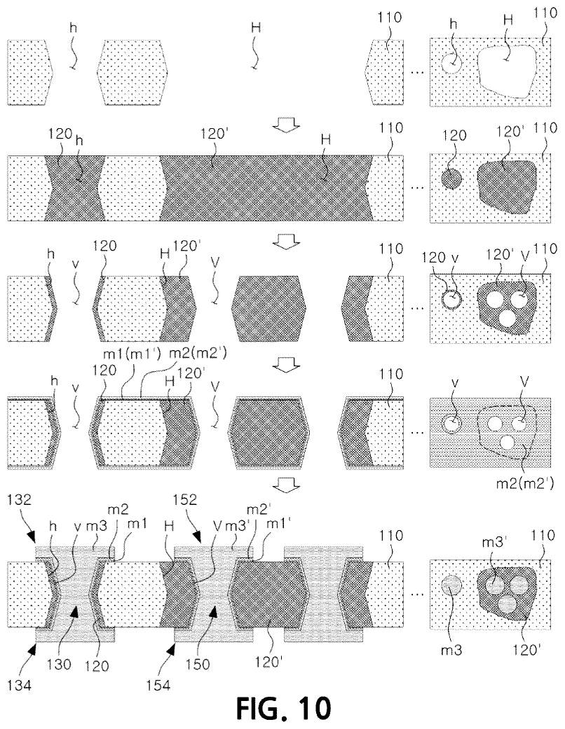

FIG. 10 is a process diagram schematically illustrating an example of manufacturing the printed circuit board of FIG. 9.

Meanwhile, the drawings on the left schematically illustrate process cross-sections, and the drawings on the right schematically illustrate top views of the process cross-sections on the left, respectively.

Referring to FIG. 10, first, the through-hole h and the through-portion H may be formed in the glass layer 110. The through-portion H may also be formed by a chemical method such as etching, blasting, laser or plasma, and/or a mechanical method, similarly to the through-hole h. The through-hole h and the through-portion H may be formed together through the same process. Next, insulating materials 120 and 120′ may be applied to the glass layer 110 to fill the through-hole h and the through-portion H, and then, portions of the insulating materials 120 and 120′ disposed on the upper surface and the lower surface of the glass layer 110 may be removed. In this process, a portion filling the through-hole h of the insulating materials 120 and 120′ may be the first insulating material 120, and a portion filling the through-portion H may be the second insulating material 120′. Next, a first via hole v may be formed in the first insulating material 120, and a plurality of second via holes V may be formed in the through-portion H. The processing of the first via hole v and the plurality of second via holes V may be performed using laser processing using carbon dioxide gas. The first via hole v and the plurality of second via holes V may be formed together through the same process. Next, by sequentially performing sputtering and electroless plating, the first and second metal layers m1 and m2 may be formed on the glass layer 110 and inside the first via hole v, and the fourth and fifth metal layers m1′ and m2′ may be formed on the glass layer 110 and inside the plurality of second via holes V. The first and second metal layers m1 and m2 and the fourth and fifth metal layers m1′ and m2′ may be formed together through the same process. Next, by a circuit process including electroless plating, the third metal layer m3 may be formed on the glass layer 110 and inside the first via hole v, and the sixth metal layer m3′ may be formed on the glass layer 110 and inside the plurality of second via holes V. The third metal layer m3 and the sixth metal layer m3′ may be formed together through the same process. Through this process, the first metal via 130, the first and second metal patterns 132 and 134, the plurality of second metal vias 150, and the plurality of third and fourth metal patterns 152 and 154 may be formed. If necessary, other metal patterns 136 and 138 described above may also be formed. The printed circuit board 100C described above may be manufactured through a series of processes. With respect to other descriptions, the contents described as being present in the examples of manufacturing printed circuit boards 100A and 100C and the printed circuit board 100A may be substantially identically applied thereto.

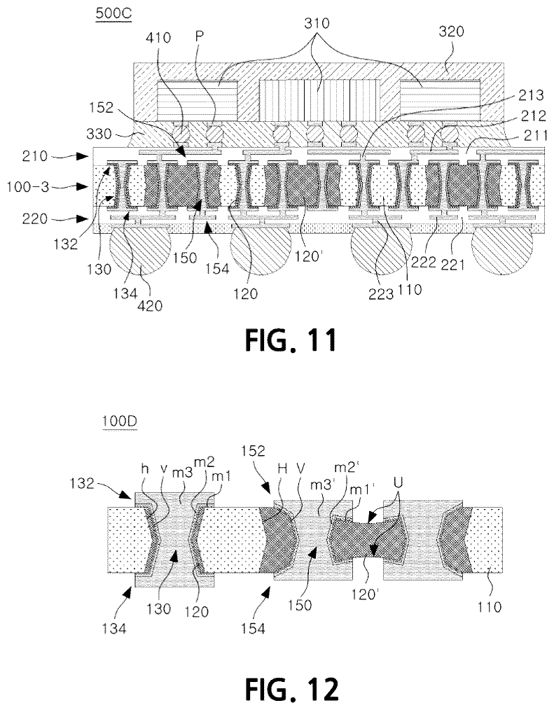

FIG. 11 is a cross-sectional view schematically illustrating a modified example of the printed circuit board of FIG. 9.

Referring to FIG. 11, a printed circuit board 500C may be configured so that the structure described as being present in the printed circuit board 100C described above instead of the structure described as being present in the printed circuit board 100A described above may be included in a core portion 100-3, in the printed circuit board 500A described above. Accordingly, the technical features and technical effects described as being present in the printed circuit boards 100A, 100C and 500A described above may be substantially identically included therein. Additionally, various shapes illustrated in FIGS. 3A to 3M may be applied to the core portion 100-3. Redundant descriptions thereof will be omitted. With respect to the other descriptions, the contents described as being present in the printed circuit boards 100A, 100C and 500A may be substantially identically applied thereto.

FIG. 12 is a cross-sectional view schematically illustrating another example of a printed circuit board.

Referring to FIG. 12, a printed circuit board 100D may be configured so that in the printed circuit board 100C described above, each of an upper surface and a lower surface of the second insulating material 120′ may have a concave portion U, and at least one or all of the plurality of second via holes V may penetrate between the concave upper and lower surfaces of the second insulating material 120′. Accordingly, the upper surface of at least one or all of the plurality of third metal patterns 152 may be disposed below the upper surface of the first metal pattern 132. Additionally, the lower surface of at least one or all of the plurality of fourth metal patterns 154 may be disposed above the lower surface of the second metal pattern 134. Additionally, the lower surface of at least one of the plurality of third metal patterns 152 or the lower surface of all thereof may be inclined. Additionally, the upper surface of at least one of the plurality of fourth metal patterns 154 or the upper surface of all thereof may be inclined.

In this manner, since the printed circuit board 100D has a structure similar to that of the printed circuit board 100C described above, it may substantially include the technical effects described above. Additionally, each of the upper surface and the lower surface of the second insulating material 120′ may have a concave portion U, and a plurality of second metal vias 150 having a smaller height or thickness may be formed in the concave portion U. This structure may be more easily applied to a via-dense region, and may reduce a height or a thickness of the via formed in the via-dense region, and may also further reduce the via pitch.

The various shapes of the through-hole h and the via hole v illustrated in FIGS. 3A to 3M may also be applied to the printed circuit board 100D. For example, the various shapes described above may be substantially identically or similarly applied to the through-hole h and the first via hole v, and the through-portion H and the plurality of second via holes V. With respect to other descriptions, the contents described as being present in the printed circuit boards 100A and 100C may be substantially identically applied thereto.

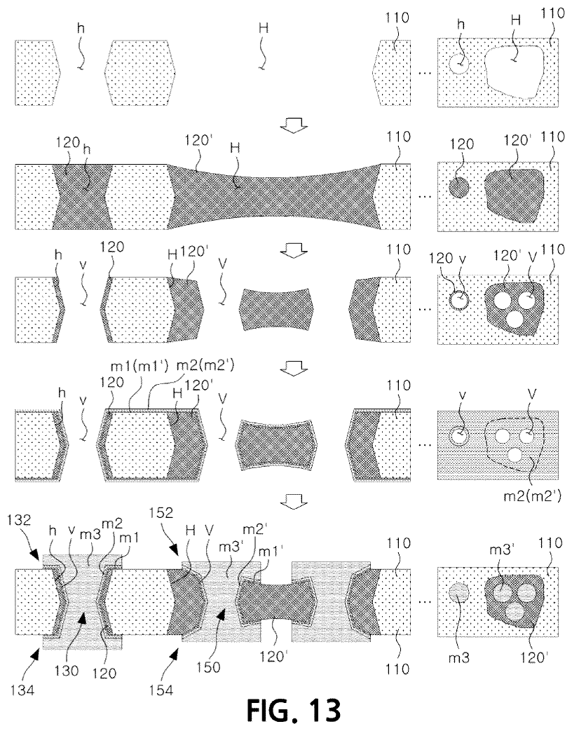

FIG. 13 is a process diagram schematically illustrating an example of manufacturing the printed circuit board of FIG. 12.

Meanwhile, the drawings on the left side schematically illustrate process cross-sections, and the drawings on the right side schematically illustrate top-views of the process cross-sections on the left side, respectively.

Referring to FIG. 13, first, the through-hole h and the through-portion H may be formed in the glass layer 110. Next, insulating materials 120 and 120′ may be applied to the glass layer 110 to fill the through-hole h and the through-portion H, and then, the portion of the insulating materials 120 and 120′ disposed on the upper surface and lower surface of the glass layer 110 may be removed. In this process, a portion of the insulating materials 120 and 120′ that fills the through-hole h may be the first insulating material 120, and a portion thereof that fills the through-portion H may be the second insulating material 120′, and in this case, in a process of filling the through-portion H and/or removing a portion of the second insulating material 120′, undulation may occur on the upper surface and/or lower surface of the second insulating material 120′. Next, a first via hole v may be formed in the first insulating material 120, and a plurality of second via holes V may be formed in the through-portion H. Next, first and second metal layers m1 and m2 may be formed on the glass layer 110 and inside the first via hole v, and fourth and fifth metal layers m1′ and m2′ may be formed on the glass layer 110 and inside the plurality of second via holes V. Next, a third metal layer m3 may be formed on the glass layer 110 and inside the first via hole v, and a sixth metal layer m3′ may be formed on the glass layer 110 and inside the plurality of second via holes V. Through this process, a first metal via 130, first and second metal patterns 132 and 134, a plurality of second metal vias 150, and a plurality of third and fourth metal patterns 152 and 154 may be formed. If necessary, other metal patterns 136 and 138 described above may also be formed. The printed circuit board 100D described above may be manufactured through a series of processes. With respect to other descriptions, the contents described in the manufacturing examples of the printed circuit boards 100A, 100C and 100D and the printed circuit boards 100A and 100C may be substantially identically applied thereto.

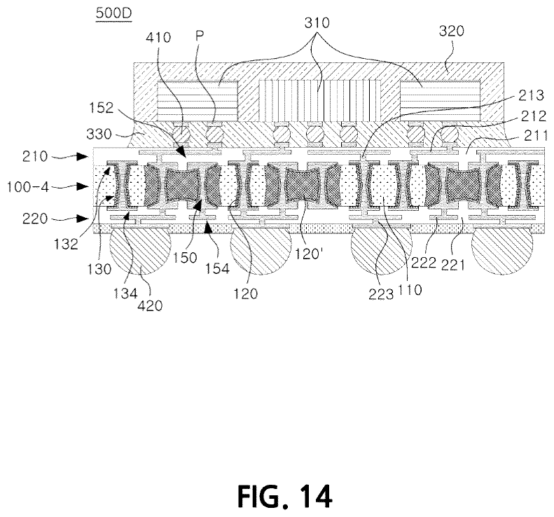

FIG. 14 is a cross-sectional view schematically illustrating a modified example of the printed circuit board of FIG. 12.

Referring to FIG. 14, a printed circuit board 500D may be configured so that the structure described as being present in the printed circuit board 100D described above instead of the structure described as being present in the printed circuit board 100C described above may be included in a core portion 100-4, in the printed circuit board 500C described above. Accordingly, the technical features and technical effects described as being present in the printed circuit boards 100A, 100C, 100D, 500A and 500C described above may be substantially identically included therein. Additionally, various shapes illustrated in FIGS. 3A to 3M may be applied to the core portion 100-4. Duplicate descriptions thereof will be omitted. Additionally, with respect to other descriptions, the contents described as being present in the printed circuit boards 100A, 100C, 100D, 500A and 500C may be substantially identically applied thereto.

In the present disclosure, being substantially conformally disposed may denote being formed along a surface (e.g., a wall surface, a bottom surface, a side surface, or the like) of a target component with a thickness of a thin film of approximately 1000 nm or less.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of at least partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, the expression ‘exposing’ may include not only completely exposing but also partially exposing, and exposing may mean exposing from the filling of the component. For example, exposing a pad through an opening may refer to exposing the pad from beneath a resist layer, and a surface treatment layer or similar feature may be additionally formed on the exposed pad.

In the present disclosure, being disposed in a through-portion, a through-hole or a via-hole may include not only a case in which an object is disposed completely in the through-portion, the through-hole or the via-hole, but also a case in which the object protrudes upwardly or downwardly in a cross-section. For example, when the object may be disposed within the through-portion, the through-hole or the via-hole on a plane, the object may be determined to be disposed within the through-portion, the through-hole or the via-hole in a broader sense.

In the present disclosure, determination may be performed by including process errors, positional deviations, errors at the time of measurement, which may occur substantially in a manufacturing process. For example, substantially perpendicular may include not only completely perpendicular but also approximately perpendicular. Furthermore, substantially coplanar may include not only the case of being completely coplanar, but also the case of being approximately coplanar.

In the present disclosure, the same insulating material may denote not only a case of being the same insulating material, but also a case of including the same type of insulating material. Accordingly, the composition of the insulating material is substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Additionally, the term electrically connected includes both physically connected and not physically connected. Additionally, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described as being present in a particular example embodiment are not described as being present in other example embodiments, they may be understood as explanations related to other example embodiments unless there is an explanation contrary to or contradictory to matters in other example embodiments.

The terms used in the present disclosure are intended solely to describe example embodiments and are not meant to limit the scope of the disclosure. In this context, singular terms also encompass their plural forms unless explicitly stated otherwise.

1. A printed circuit board, comprising:
a glass layer having a through-hole;
a first insulating material disposed within the through-hole and having a first via hole; and
a first metal via disposed within the first via hole,
wherein the first metal via includes a first metal layer in which at least a portion thereof is disposed on a wall surface of the first via hole, a second metal layer in which at least a portion thereof is disposed on the first metal layer, and a third metal layer disposed on the second metal layer and filling at least a portion of the first via hole.

2. The printed circuit board according to claim 1, wherein the first insulating material includes an organic insulating material,
the first metal layer includes a sputtered metal,
the second metal layer includes chemical copper, and
the third metal layer includes electrolytic copper.

3. The printed circuit board according to claim 2, wherein the first metal layer includes a first sputtering layer connected to the wall surface of the first via hole and a second sputtering layer connected to the chemical copper,
the first sputtering layer includes titanium, and
the second sputtering layer includes copper.

4. The printed circuit board according to claim 1, wherein the second metal layer has a greater thickness than the first metal layer.

5. The printed circuit board according to claim 1, further comprising:
a first metal pattern connected to an upper side of the first metal via; and
a second metal pattern connected to a lower side of the first metal via,
wherein the first metal pattern includes the first metal layer extending onto an upper surface of the first insulating material and an upper surface of the glass layer, the second metal layer extending onto the first metal layer from the upper surface of the first insulating material and the upper surface of the glass layer, and the third metal layer extending onto the second metal layer from the upper surface of the first insulating material and the upper surface of the glass layer and protruding to an upper side of the first via hole, and
the second metal pattern includes the first metal layer extending onto a lower surface of the first insulating material and a lower surface of the glass layer, the second metal layer extending onto the first metal layer from the lower surface of the first insulating material and the lower surface of the glass layer, and the third metal layer extending onto the second metal layer from the lower surface of the first insulating material and the lower surface of the glass layer and protruding to a lower side of the first via hole.

6. The printed circuit board according to claim 5, wherein the extending portion of the first metal layer is in direct contact with the upper surface and the lower surface of the first insulating material, and the upper surface and the lower surface of the glass layer, respectively.

7. The printed circuit board according to claim 5, wherein the upper surface of the first insulating material is substantially coplanar with the upper surface of the glass layer, and
the lower surface of the first insulating material is substantially coplanar with the lower surface of the glass layer.

8. The printed circuit board according to claim 5, wherein the upper surface of the first insulating material is recessed downwardly from the upper surface of the glass layer,
the lower surface of the first insulating material is recessed upwardly from the lower surface of the glass layer,
the first metal pattern has a step structure on the upper surface of the first insulating material, and
the second metal pattern has a step structure on the lower surface of the first insulating material.

9. The printed circuit board according to claim 1, wherein in a cross-section penetrating through the through-hole and the first via hole,
a shape of the through-hole and a shape of the first via hole are formed independently.

10. The printed circuit board according to claim 1, wherein the glass layer further has a through-portion spaced apart from the through-hole,
a second insulating material having a plurality of second via holes is disposed within the through-portion, and
a plurality of second metal vias are disposed within the plurality of second via holes, respectively,
wherein each of the plurality of second metal vias includes a fourth metal layer in which at least a portion thereof is disposed on a wall surface of each of the plurality of second via holes, a fifth metal layer in which at least a portion thereof is disposed on the fourth metal layer on the wall surface of each of the plurality of second via holes, and a sixth metal layer disposed on the fifth metal layer and filling at least a portion of each of the plurality of second via holes.

11. The printed circuit board according to claim 10, wherein the second insulating material includes an organic insulating material,
the fourth metal layer includes a sputtered metal,
the fifth metal layer includes chemical copper, and
the sixth metal layer includes electrolytic copper.

12. The printed circuit board according to claim 10, wherein the plurality of second metal vias are connected to a plurality of third metal patterns on an upper side, respectively, and
the plurality of second metal vias are connected to a plurality of fourth metal patterns on a lower side, respectively,
wherein each of the plurality of third metal patterns includes the fourth metal layer extending onto an upper surface of the second insulating material, the fifth metal layer extending onto the fourth metal layer from the upper surface of the second insulating material, and the sixth metal layer extending onto the fifth metal layer from the upper surface of the second insulating material and protruding to an upper side of each of the plurality of second via holes, and
each of the plurality of fourth metal patterns includes the fourth metal layer extending onto a lower surface of the second insulating material, the fifth metal layer extending onto the fourth metal layer from the lower surface of the second insulating material, and the sixth metal layer extending onto the fifth metal layer from the lower surface of the second insulating material and protruding to a lower side of each of the plurality of second via holes.

13. The printed circuit board according to claim 10, wherein each of the upper surface and the lower surface of the second insulating material has a concave portion, and
at least one of the plurality of second via holes penetrates between a concave upper surface and a concave lower surface of the second insulating material.

14. The printed circuit board according to claim 13, further comprising:
a plurality of third metal patterns respectively connected to an upper side of each of the plurality of second metal vias;
a plurality of fourth metal patterns respectively connected to a lower side of each of the plurality of second metal vias;
a first metal pattern connected to an upper side of the first metal via; and
a second metal pattern connected to a lower side of the first metal via,
wherein an upper surface of at least one of the plurality of third metal patterns is disposed below an upper surface of the first metal pattern, and
a lower surface of at least one of the plurality of fourth metal patterns is disposed above a lower surface of the second metal pattern.

15. The printed circuit board according to claim 1, wherein at least another portion of the second metal layer is in direct contact with the first insulating material in a central portion of the first via hole.

16. A printed circuit board, comprising:
a core portion including a glass core having a through-hole, an insulating material disposed within the through-hole and having a via hole, and a metal via disposed within the via hole; and
a build-up portion including an insulating body disposed on the core portion, one or more interconnection layers respectively disposed on or within the insulating body, and one or more via layers respectively disposed within the insulating body,
wherein the metal via includes a first metal layer in which at least a portion thereof is conformally disposed on a wall surface of the via hole, a second metal layer in which at least a portion thereof is conformally disposed on the first metal layer, and a third metal layer disposed on the second metal layer and filling at least a portion of the via hole.

17. The printed circuit board according to claim 16, further comprising:
a semiconductor chip mounted on the build-up portion.

18. A printed circuit board, comprising:
a glass layer having a through-hole;
a first insulating material disposed within the through-hole and having a first via hole; and
a first metal via disposed within the first via hole,
wherein the first metal via includes:
a first metal layer in which at least a portion thereof is disposed on a wall surface of the first via hole;
a second metal layer in which at least a portion thereof is disposed on the first metal layer; and
a third metal layer disposed on the second metal layer and filling at least a portion of the first via hole,
wherein a nano void is formed at a boundary between the second metal layer and the first metal layer.

19. The printed circuit board according to claim 18,
wherein the first metal layer includes a sputtered copper layer and the second metal layer includes chemical copper.

20. The printed circuit board according to claim 18,
wherein the nano void is observable using a scanning electron microscope (SEM), a transmission electron microscope (TEM), a scanning transmission electron microscope (STEM), or a focused ion beam (FIB).
